(19) United States
(12) Patent Application Publication
(10) Pub. No.: US 2017/0018563 A1
(43) Pub. Date: Jan. 19, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Daisuke Nishida, Mie (JP)

(73) Assignee: Kabushiki Kaisha Toshiba, Minato-ku (JP)

(21) Appl. No.: 14/846,052

(22) Filed: Sep. 4, 2015

Related U.S. Application Data
(60) Provisional application No. 62/191,784, filed on Jul. 13, 2015.

(51) Int. Cl. H01L 27/115; H01L 21/28

(52) U.S. Cl. CPC H01L 27/11582; H01L 27/11568; H01L 21/28282

(57) ABSTRACT

According to one embodiment, a semiconductor memory device includes a stacked body including a plurality of electrode films and a plurality of insulating films, the plurality of electrode films and the plurality of insulating films being alternately stacked on each other, a semiconductor pillar extending in a stacking direction of the stacked body, and a charge storage film provided between the electrode films and the semiconductor pillar and extending linearly in the stacking direction of the stacked body. A stacking-direction width of an edge portion of the electrode films on side of the semiconductor pillar is shorter than a stacking-direction width of the electrode films other than the edge portion of the electrode films.

### CROSS-REFERENCE TO RELATED APPLICATION

This application is based upon and claims the benefit of priority from U.S. Provisional Patent Application 62/191,784, filed on Jul. 13, 2015; the entire contents of which are incorporated herein by reference.

### FIELD

Embodiments described herein relate generally to a semiconductor memory device and a method for manufacturing the same.

### BACKGROUND

Conventionally, flash memories have been fabricated by two-dimensionally integrating elements on a silicon substrate. In this type of flash memory, the storage capacity is increased by downsizing each element to achieve miniaturization. In recent years, however, it is becoming difficult in terms of technology and cost to increase the storage capacity through miniaturization.

In order to solve such a problem, three-dimensionally stacked semiconductor memory devices including memory cells stacked on a substrate are proposed. Some of the three-dimensionally stacked semiconductor memory devices adopt MONOS (Metal Oxide Nitride Oxide Semiconductor) transistors as memory cells. In this type of semiconductor memory device, ensuring reliability is demanded.

### BRIEF DESCRIPTION OF THE DRAWINGS

FIG. 1 is a perspective view illustrating a semiconductor memory device according to the embodiment;

FIG. 2 is a cross-sectional view illustrating a cross-section of the semiconductor memory device according to the embodiment taken along the line A1-A2 shown in FIG. 1;

FIG. 3 is an enlarged view of a portion B of the semiconductor memory device according to the embodiment shown in FIG. 2;

FIG. 4A to FIG. 6B are process cross-sectional views illustrating a method for manufacturing the semiconductor memory device according to the embodiment;

FIG. 7 is a cross-sectional view illustrating a cross-section of a semiconductor memory device according to the second embodiment, corresponding to the cross-section taken along the line A1-A2 shown in FIG. 1; and

FIG. 8A and FIG. 8B are process cross-sectional views illustrating the method for manufacturing the semiconductor memory device according to the embodiment.

### DETAILED DESCRIPTION

According to one embodiment, a semiconductor memory device includes a stacked body including a plurality of electrode films and a plurality of insulating films, the plurality of electrode films and the plurality of insulating films being alternately stacked on each other, a semiconductor pillar extending in a stacking direction of the stacked body, and a charge storage film provided between the electrode films and the semiconductor pillar and extending linearly in the stacking direction of the stacked body. A stacking-direction width of an edge portion of the electrode films on side of the semiconductor pillar is shorter than a stacking-direction width of the electrode films other than the edge portion of the electrode films.

Various embodiments will be described hereinafter with reference to the accompanying drawings.

### First Embodiment

First, a first embodiment will be described.

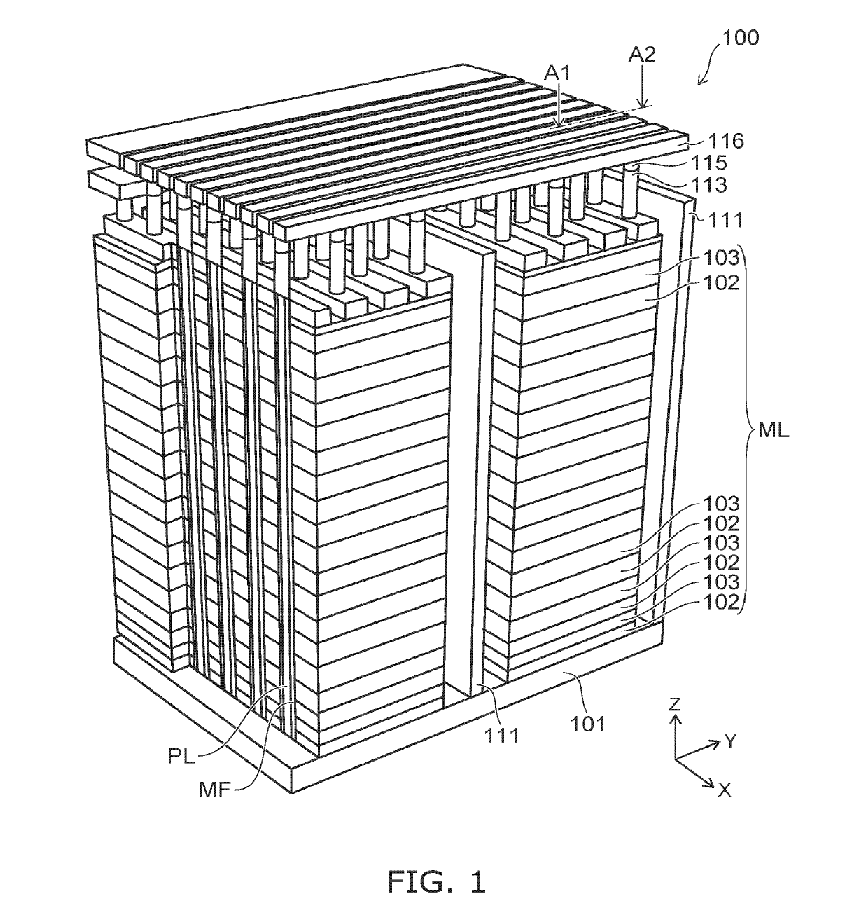

FIG. 1 is a perspective view illustrating a semiconductor memory device according to the embodiment.

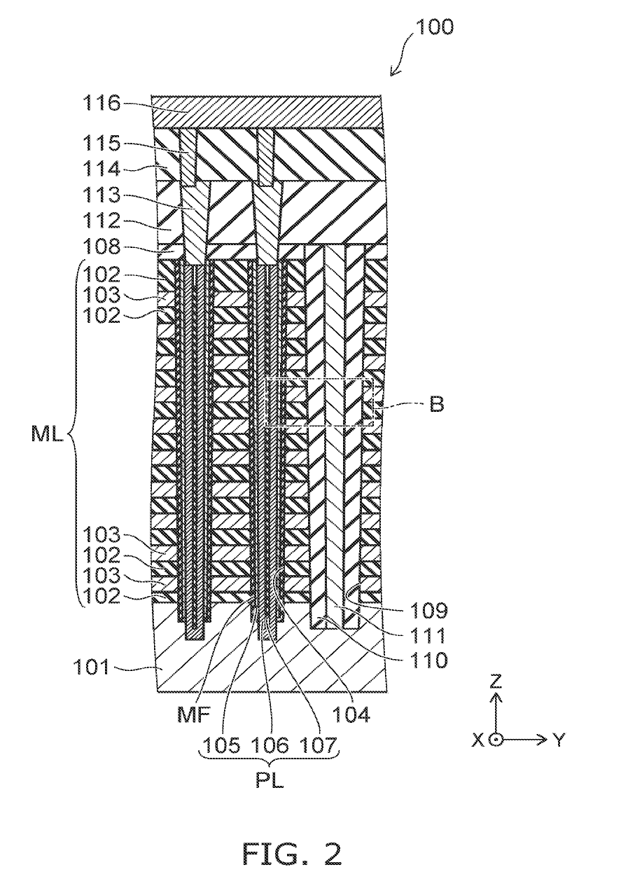

FIG. 2 is a cross-sectional view illustrating a cross-section of the semiconductor memory device according to the embodiment taken along the line A1-A2 shown in FIG. 1.

As shown in FIG. 1, the semiconductor memory device 100 according to the embodiment is provided with a semiconductor substrate 101.

Hereinafter, in the specification, an XYZ orthogonal coordinate system is introduced for convenience of description. In the coordinate system, two directions parallel to a major surface of the semiconductor substrate 101 and orthogonal to each other are referred to as “X-direction” and “Y-direction”, and a direction orthogonal to both the X-direction and the Y-direction is referred to as “Z-direction”.

A plurality of inter-electrode insulating films 102 and a plurality of electrode films 103 are provided on the semiconductor substrate 101. The plurality of inter-electrode insulating films 102 and the plurality of electrode films 103 are alternately stacked on each other to form a stacked body ML. The inter-electrode insulating film 102 is formed of an insulative material such as silicon oxide. The electrode film 103 is formed of a conductive material such as tungsten.

As shown in FIG. 2, memory holes 104 having a cylindrical shape and extending in the Z-direction are formed in the stacked body ML. The memory hole 104 reaches an upper layer portion of the semiconductor substrate 101. In the memory hole 104, a memory film MF is provided on a side surface of the stacked body ML. Moreover, a semiconductor film 105 is provided on a side surface of the memory film MF in the memory hole 104. Further, a semiconductor film 106 is provided on a side surface of the semiconductor film 105 in the memory hole 104. The memory hole 104 is filled with an insulating member 107. The semiconductor films 105 and 106 and the insulating member 107 configure a semiconductor pillar PL.

An insulating film 108 is provided on the stacked body ML. Slits 109 that penetrate the insulating film 108 and the stacked body ML are formed. The slit 109 reaches the upper layer portion of the semiconductor substrate 101. The shape of the slit 109 is a trench form extending in the X-direction. The slit 109 is formed at a portion spaced from the memory hole 104. An insulating film 110 is provided on a side surface of the stacked body ML in the slit 109. The interior of the slit 109 is filled with a conductive member 111. The semiconductor pillar PL and the conductive member 111 are connected through the semiconductor substrate 101.

An insulating film 112 is provided on the insulating film 108.

Plugs 113 that penetrate the insulating films 112 and 108 are provided each at a region directly on the semiconductor pillar PL. The plug 113 is connected to the semiconductor pillar PL. An insulating film 114 is provided on the insulating film 112.

Plugs 115 that penetrate the insulating film 114 are provided each at a region directly on the plug 113. Bit lines 116 are provided on the insulating film 114 and the plugs 115. The plug 115 is connected to the bit line 116.

Next, a configuration of the semiconductor memory device 100 according to the embodiment at the memory hole 104 and its surroundings will be described.

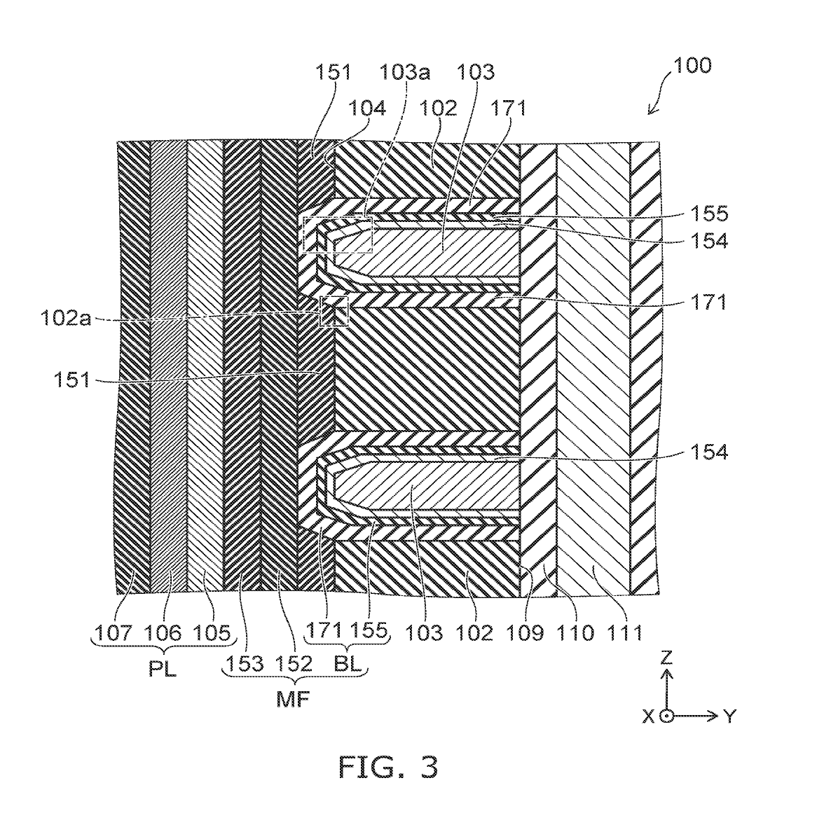

FIG. 3 is an enlarged view of a portion B of the semiconductor memory device according to the embodiment shown in FIG. 2.

As shown in FIG. 3, a cover insulating film 151 is provided on a side surface of the inter-electrode insulating film 102 on the memory hole 104 side. Moreover, a barrier metal film 154 is provided on an upper surface, a lower surface, and a memory-hole-104-side side surface of the electrode film 103. The barrier metal film 154 is formed of a conductive material such as titanium nitride. An aluminum oxide film 155 that covers the barrier metal film 154 is provided on the barrier metal film 154. A silicon oxide film 171 that covers the aluminum oxide film 155 is provided on the aluminum oxide film 155. The aluminum oxide film 155 and the silicon oxide film 171 configure a block insulating film BL.

A charge storage film 152 having a cylindrical shape with a substantially uniform inside diameter is provided in the memory hole 104. The charge storage film 152 is disposed on the silicon oxide film 171 and a side surface of the cover insulating film 151 in the memory hole 104. In this case, a Z-direction thickness of the silicon oxide film 171 between the electrode film 103 and the charge storage film 152 decreases from the electrode film 103 toward the charge storage film 152. A tunnel insulating film 153 having a cylindrical shape with a substantially uniform inside diameter is provided on an inner surface of the charge storage film 152.

The block insulating film BL, the charge storage film 152, and the tunnel insulating film 153 configure the memory film MF.

The block insulating film BL is a film that does not substantially allow a current to flow therethrough even with the application of a voltage within the range of drive voltage of the semiconductor memory device 100. The charge storage film 152 is, for example, a film having the ability to store charge, such as a silicon nitride film. The tunnel insulating film 153 is a film that usually has an insulating property but allows a tunnel current to flow therethrough in response to the application of a predetermined voltage within the range of drive voltage of the semiconductor memory device 100. The tunnel insulating film 153 is, for example, a silicon oxide film.

The block insulating film BL configuring the memory film MF and the barrier metal film 154 are disposed between the inter-electrode insulating film 102 and the electrode film 103, but the block insulating film BL and the barrier metal film 154 are not shown in FIG. 1 and FIG. 2 for the simplicity of the drawings.

The width of an edge portion of the electrode film 103 on the semiconductor pillar PL side, that is, a Z-direction length, is shorter than a Z-direction width of the electrode film 103 other than the edge portion. The edge portion of the electrode film 103 on the semiconductor pillar PL side becomes continuously shorter toward a side surface of the electrode film 103 on the semiconductor pillar PL side, and is rounded. Moreover, the curvature of a corner portion 103a above or below the middle point of the edge portion of the electrode film 103 on the semiconductor pillar PL side is smaller the curvature of a corner portion 102a of an edge portion of the inter-electrode insulating film 102 on the semiconductor pillar PL side.

Further, the barrier metal film 154 covering the edge portion of the electrode film 103 is curved along the corner portion 103a of the electrode film 103. The curvature of the curved portion of the barrier metal film 154 covering the edge portion of the electrode film 103 is smaller than the curvature of the corner portion 102a of the edge portion of the inter-electrode insulating film 102.

Next, a method for manufacturing the semiconductor memory device 100 according to the embodiment will be described.

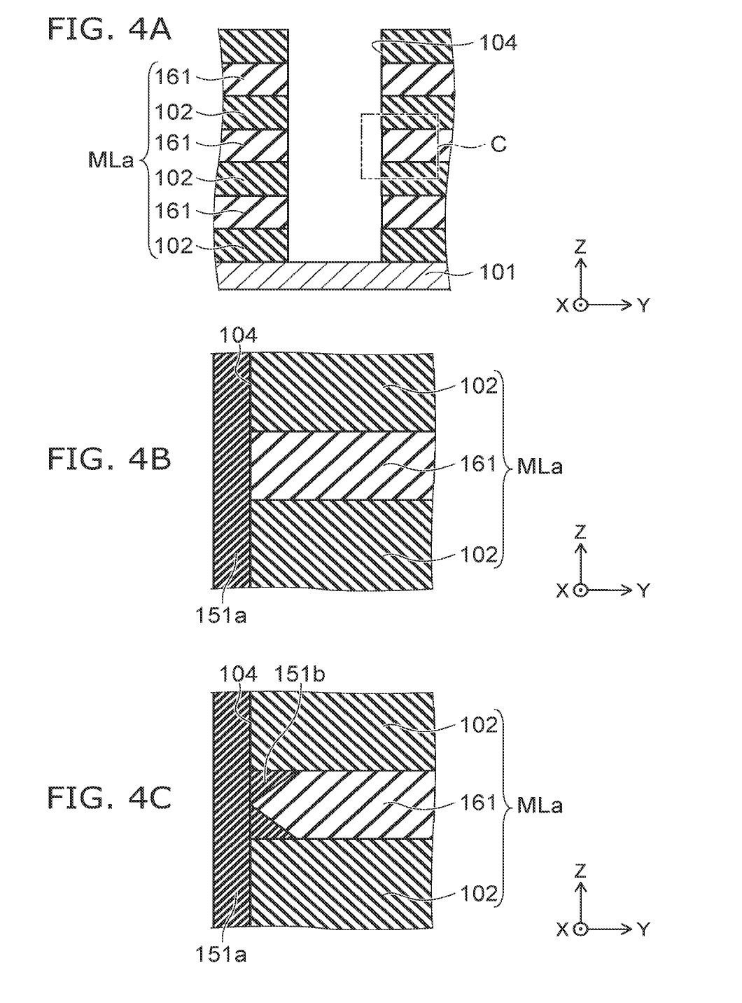

FIG. 4A to FIG. 6B are process cross-sectional views illustrating the method for manufacturing the semiconductor memory device according to the embodiment. Moreover, FIG. 4B to FIG. 6B are enlarged views of a portion corresponding to a portion C shown in FIG. 4A.

First, as shown in FIG. 4A, the semiconductor substrate 101 is prepared. Next, the inter-electrode insulating films 102 and sacrificial films 161 are alternately stacked on each other on the semiconductor substrate 101 to form a stacked body MLa. The sacrificial film 161 contains silicon nitride. Thereafter, the memory hole 104 that penetrates the stacked body MLa is formed by anisotropic etching such as RIE (Reactive Ion Etching). Due to this, an upper surface of the semiconductor substrate 101 is exposed in the memory hole 104.

Next, as shown in FIG. 4B, silicon oxide is deposited on an inner surface of the memory hole 104 by ALD (Atomic Layer Deposition) to form a cover insulating film 151a.

Next, as shown in FIG. 4C, a portion of the sacrificial film 161 is oxidized through the cover insulating film 151a. The sacrificial film 161 is oxidized by radical oxidation, plasma oxidation, or ISSG (in Situ Steam Generation) oxidation, or an oxidation method such as LPRO (Low-Pressure Radical Oxidation). In this case, at an edge portion of the stacked body MLa on the memory hole 104 side, radical species such as radicals or OH radicals diffuse into the inter-electrode insulating films 102 disposed above and below the sacrificial film 161. Since the radical species that have diffused into the inter-electrode insulating films 102 also oxidize an edge portion of the sacrificial film 161, the oxidation from the memory hole 104 side proceeds deeper closer to an upper surface or a lower surface of the sacrificial film 161 at the edge portion thereof. Due to this, a portion of the sacrificial film 161 including the side surface on the memory hole 104 side is turned into a cover insulating film 151b. In this case, the side surface of the sacrificial film 161 has a bird's beak shape. The side surface of the sacrificial film 161 may be rounded. With this oxidation process, the cover insulating film 151a is densified and thus turned into the cover insulating film 151 with improved film quality.

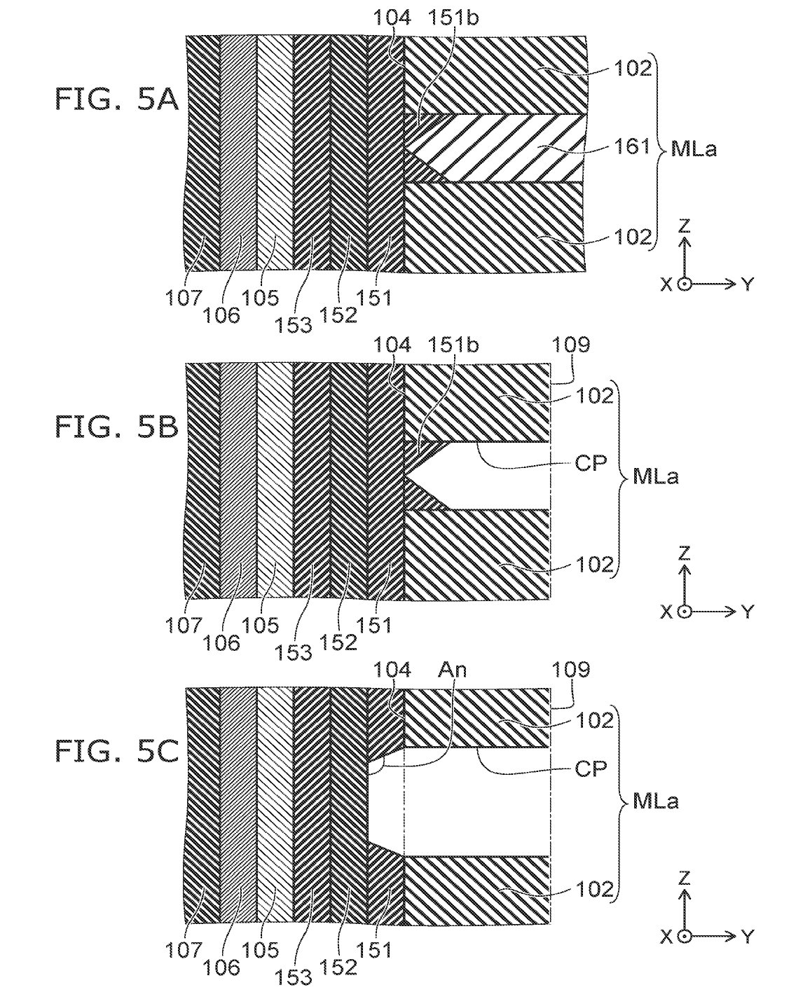

Next, as shown in FIG. 5A, silicon nitride is deposited on a side surface of the cover insulating film 151 in the memory hole 104, to thereby form the charge storage film 152. In this case, a portion of the charge storage film 152, which covers a side surface of the stacked body MLa, is formed linearly along the Z-direction. The tunnel insulating film 153 is formed by depositing silicon oxide on a side surface of the charge storage film 152. Thereafter, a semiconductor material such as amorphous silicon is deposited on a side surface of the tunnel insulating film 153, to thereby form the semiconductor film 105. In this case, the semiconductor film 105 is formed also on the bottom of the memory hole 104. However, since the tunnel insulating film 153, the charge storage film 152, and the cover insulating film 151 lie between the semiconductor film 105 and the semiconductor substrate 101, the semiconductor film 105 is not connected with the semiconductor substrate 101.

Next, the semiconductor film 105, the tunnel insulating film 153, the charge storage film 152, and the cover insulating film 151 that are formed on the bottom of the memory hole 104 are removed by anisotropic etching such as RIE. Due to this, although not shown in the drawing, the upper surface of the semiconductor substrate 101 is exposed in the bottom of the memory hole 104. Then, the semiconductor film 106 is formed on a side surface of the semiconductor film 105 and on the exposed surface of the semiconductor substrate 101 in the memory hole 104. The semiconductor film 106 is formed of, for example, a semiconductor material such as amorphous silicon. The semiconductor film 106 is connected to the semiconductor substrate 101 at the bottom surface of the memory hole 104. Thereafter, the insulating member 107 is formed by filling the interior of the memory hole 104 with silicon oxide.

Next, as shown in FIG. 5B, the slit 109 extending in the X-direction and penetrating the stacked body MLa is formed spaced from the memory hole 104 by performing anisotropic etching such as RIE. Thereafter, the sacrificial film 161 is removed by performing wet etching through the slit 109. In this etching, the cover insulating film 151b serves as etching stopper. With the removal of the sacrificial film 161, a recess CP is formed in the stacked body MLa. In this case, the portion of the sacrificial film 161, which has been oxidized and turned into the cover insulating film 151b, remains. Due to this, a depth surface of the recess CP, that is, a surface of the cover insulating film 151b in the recess CP, has a triangularly depressed shape reflecting the bird's beak shape of the sacrificial film 161. For the wet etching in this case, a chemical solution that selectively dissolves the sacrificial film 161, such as hot phosphoric acid, is used.

Next, as shown in FIG. 5C, a portion of the cover insulating film 151 between the recess CP and the charge storage film 152 and the cover insulating film 151b are removed by performing wet etching again through the slit 109. For the wet etching in this case, a chemical solution such as DMF (N,N-dimethylformamide) is used. Due to this, a portion of a side surface of the charge storage film 152 is exposed in the recess CP. Since the cover insulating film 151b is etched so as to inherit the triangularly depressed shape of the surface in the recess CP as viewed from the X-direction, an angle An formed between an exposed surface of the cover insulating film 151 and the exposed surface of the charge storage film 152 after the etching process is larger than a right angle. With this etching, portions of the inter-electrode insulating films 102, which face the recess CP, are also etched, so that a Z-direction length of the recess CP is increased.

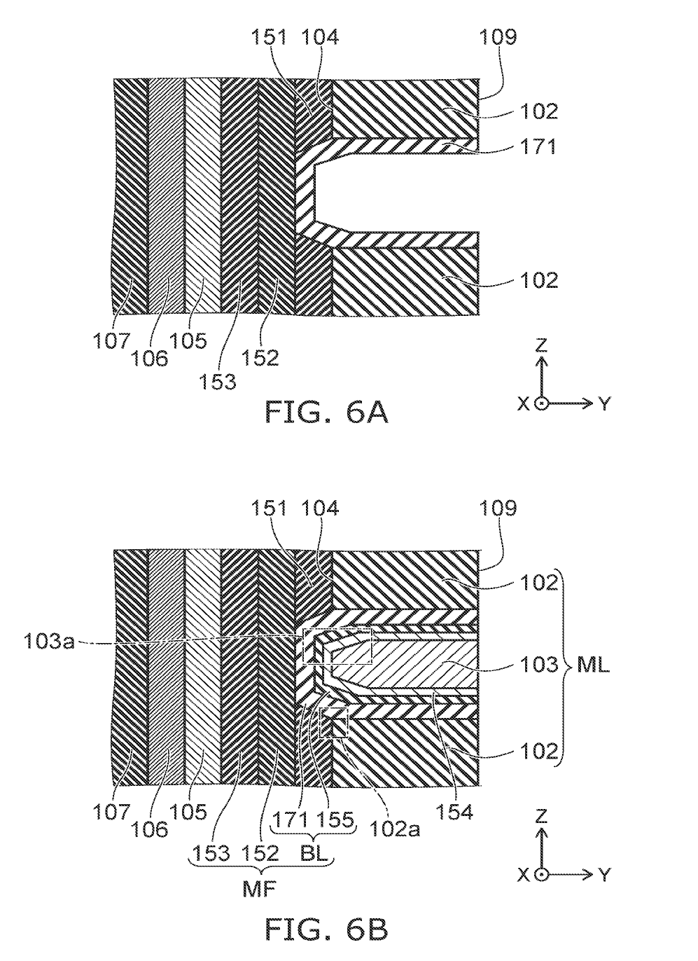

Next, as shown in FIG. 6A, the silicon oxide film 171 is formed on an upper surface and a lower surface of the inter-electrode insulating films 102 and on the exposed surface of the charge storage film 152 by depositing silicon oxide through the slit 109.

Next, as shown in FIG. 6B, the aluminum oxide film 155 is formed, through the slit 109, on the exposed surface of the cover insulating film 151 between the inter-electrode insulating films 102 adjacent to each other in the Z-direction. Moreover, the barrier metal film 154 is formed, through the slit 109, on an exposed surface of the aluminum oxide film 155. The barrier metal film 154 contains a conductive material such as titanium nitride. Thereafter, the interior of the slit 109 is filled with a metal material such as tungsten. This metal material also fills a space between the inter-electrode insulating films 102 adjacent to each other in the Z-direction, that is, the recess CP. Thereafter, the metal material is removed from within the slit 109 by anisotropic etching such as RIE. In this case, the metal material is caused to remain in the recess CP. Due to the metal material remaining therein, the electrode film 103 is formed. Due to this, the stacked body MLa is turned into the stacked body ML. The width of an edge portion of the formed electrode film 103 on the semiconductor pillar PL side, that is, a Z-direction length, is shorter than a Z-direction width of the electrode film 103 other than the edge portion. Moreover, the edge portion of the electrode film 103 on the semiconductor pillar PL side becomes continuously shorter toward the side surface on the semiconductor pillar PL side, and is rounded. In this case, the curvature of the corner portion 103a above or below the middle point of the edge portion of the electrode film 103 on the semiconductor pillar PL side is smaller than the curvature of the corner portion 102a of the edge portion of the inter-electrode insulating film 102 on the semiconductor pillar PL side. Moreover, the curvature of the curved portion of the barrier metal film 154 covering the edge portion of the electrode film 103 is smaller than the curvature of the corner portion 102a of the edge portion of the inter-electrode insulating film 102.

Next, as shown in FIG. 3, the insulating film 110 is formed on a side surface of the slit 109. Thereafter, the slit is filled with a metal material, so that the conductive member 111 is formed.

Thereafter, a normal process is carried out, so that the semiconductor memory device 100 according to the embodiment is manufactured.

Next, advantages of the embodiment will be described.

In the semiconductor memory device 100 according to the embodiment, as shown in FIG. 3, the Z-direction width of the edge portion of the electrode film 103 on the semiconductor pillar PL side is shorter than the Z-direction width of the electrode film 103 other than the edge portion. Moreover, the Z-direction width of the edge portion of the electrode film 103 on the semiconductor pillar PL side becomes continuously shorter toward the side surface on the semiconductor pillar PL side, and is rounded. Due to this, the concentration of electric field at the edge portion of the electrode film 103 can be suppressed. By suppressing the concentration of electric field at the edge portion of the electrode film 103, the degradation of the electrode film 103 or the cover insulating film 151 around the electrode film 103 can be suppressed. Since the degradation of the cover insulating film 151 can be suppressed between the electrode film 103 and the charge storage film 152, the degradation of charge retention characteristics can be suppressed. As a result, read disturbance caused by film degradation can be suppressed.

In the embodiment, after the cover insulating film 151a is formed by ALD, an oxidation process in which the sacrificial film 161 is oxidized through the cover insulating film 151a by radical oxidation, plasma oxidation, or ISSG (in Situ Steam Generation) oxidation, or an oxidation method such as LPRO (Low-Pressure Radical Oxidation) is carried out. Due to this, since the cover insulating film 151a is densified, film quality is improved.

Hence, the reliability of the semiconductor memory device 100 against stress is improved.

If a sharp corner portion is formed in an electrode film corresponding to the electrode film 103, an electric field is concentrated on the corner portion during the operation of the semiconductor memory device, so that the portion at which the electric field concentration occurs may be degraded.

### Second Embodiment

Next, a second embodiment will be described.

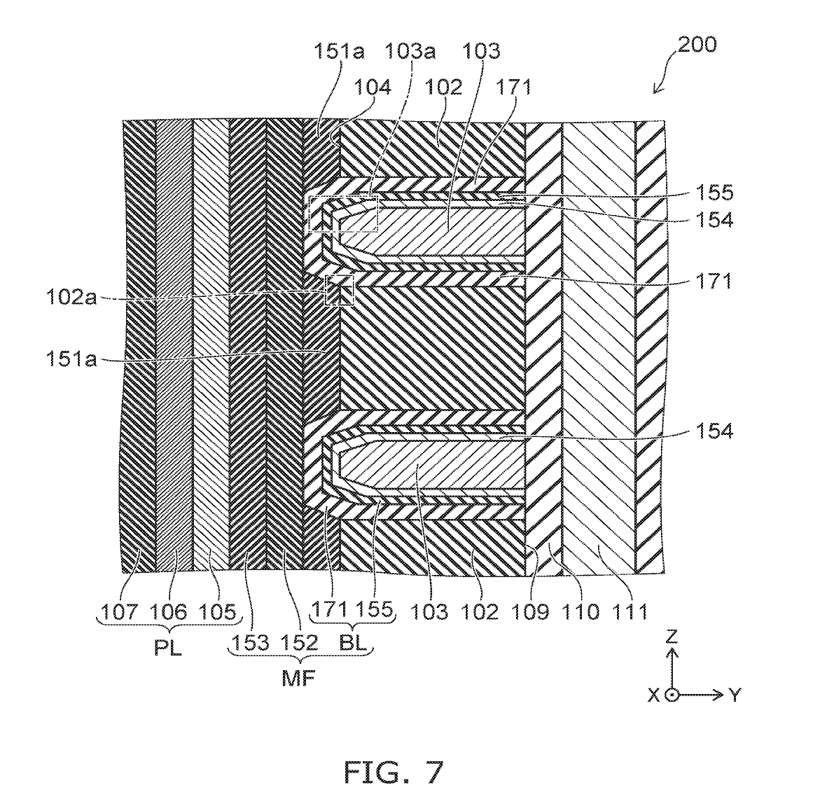

FIG. 7 is a cross-sectional view illustrating a cross-section of a semiconductor memory device according to the second embodiment, corresponding to the cross-section taken along the line A1-A2 shown in FIG. 1.

As shown in FIG. 7, the configuration of the semiconductor memory device 200 according to the embodiment is similar to that of the semiconductor memory device 100 according to the first embodiment, except for a configuration in which the cover insulating film 151a is provided instead of the cover insulating film 151.

Next, a method for manufacturing the semiconductor memory device 200 according to the embodiment will be described.

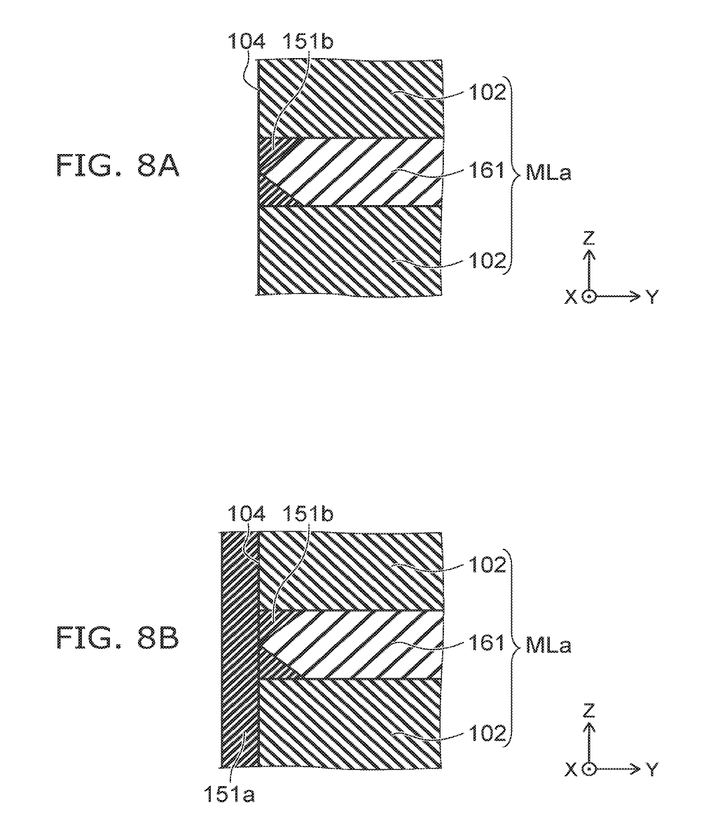

FIG. 8A and FIG. 8B are process cross-sectional views illustrating the method for manufacturing the semiconductor memory device according to the embodiment.

First, the process shown in FIG. 4A is carried out similarly to the first embodiment.

Next, as shown in FIG. 8A, a portion of the sacrificial film 161 is oxidized through the memory hole 104. The sacrificial film 161 is oxidized by radical oxidation, plasma oxidation, or ISSG (in Situ Steam Generation) oxidation, or an oxidation method such as LPRO (Low-Pressure Radical Oxidation). In this case, at an edge portion of the stacked body MLa on the memory hole 104 side, radical species such as 0 radicals or OH radicals diffuse into the inter-electrode insulating films 102 disposed above and below the sacrificial film 161. Since the radical species that have diffused into the inter-electrode insulating films 102 also oxidize an edge portion of the sacrificial film 161, the oxidation from the memory hole 104 side proceeds deeper closer to an upper surface or a lower surface of the sacrificial film 161 at the edge portion thereof. Due to this, a portion of the sacrificial film 161 including the side surface in the memory hole 104 is turned into the cover insulating film 151b. In this case, the side surface of the sacrificial film 161 on the memory hole 104 side has a bird's beak shape as viewed from the Z-direction. In this case, the side surface of the sacrificial film 161 may be rounded.

Next, as shown in FIG. 8B, silicon oxide is deposited on a side surface of the stacked body MLa and on an exposed surface of the semiconductor substrate 101 in the memory hole 104 by ALD to form the cover insulating film 151a.

Next, the processes shown in FIG. 5A to FIG. 6B are carried out similarly to the first embodiment, and thereafter, a normal process is carried out, so that the semiconductor memory device according to the embodiment is manufactured.

Next, advantages of the embodiment will be described.

In the embodiment, before the cover insulating film 151a is formed on the side surface of the stacked body MLa and on the exposed surface of the semiconductor substrate 101 in the memory hole 104, the cover insulating film 151b is formed by oxidizing the sacrificial film 161. Due to this, since the sacrificial film 161 is oxidized without using the cover insulating film 151a, the oxidation of the sacrificial film 161 is facilitated.

Moreover, similarly to the first embodiment, the width of the edge portion of the electrode film 103 on the semiconductor pillar PL side is shorter than the Z-direction width of the electrode film 103 other than the edge portion. Moreover, the edge portion of the electrode film 103 on the semiconductor pillar PL side becomes continuously shorter toward a side surface of the electrode film 103 on the semiconductor pillar PL side, and is rounded. Due to this, the concentration of electric field at the edge portion of the electrode film 103 can be suppressed. By suppressing the concentration of electric field at the edge portion of the electrode film 103, the degradation of the electrode film 103 or the cover insulating film 151a around the electrode film 103 can be suppressed. That is, since the degradation of the cover insulating film 151a can also be suppressed between the electrode film 103 and the charge storage film 152, the degradation of charge retention characteristics can be suppressed. As a result, read disturbance caused by film degradation can be suppressed.

According to the embodiments described above, it is possible to realize a semiconductor memory device with high reliability against stress and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a stacked body including a plurality of electrode films and a plurality of insulating films, the plurality of electrode films and the plurality of insulating films being alternately stacked on each other;
a semiconductor pillar extending in a stacking direction of the stacked body; and
a charge storage film provided between the electrode films and the semiconductor pillar and extending linearly in the stacking direction of the stacked body,
a stacking-direction width of an edge portion of the electrode films on side of the semiconductor pillar being shorter than a stacking-direction width of the electrode films other than the edge portion of the electrode films.

2. The semiconductor memory device according to claim 1, wherein
a corner of the edge portion of the electrode films on the semiconductor pillar side is rounded.

3. The semiconductor memory device according to claim 1, wherein
a curvature of a corner portion of the edge portion of the electrode films is smaller than a curvature of a corner portion of an edge portion of the insulating films.

4. The semiconductor memory device according to claim 1, further comprising a barrier metal film covering an upper surface, a lower surface, and a semiconductor-pillar-side side surface of the electrode films.

5. The semiconductor memory device according to claim 4, wherein
the barrier metal film covering the edge portion of the electrode films is curved along a corner portion of the edge portion of the electrode films.

6. The semiconductor memory device according to claim 5, wherein
a curvature of a curved portion of the barrier metal film covering the edge portion of the electrode films is smaller than a curvature of a corner portion of an edge portion of the insulating films.

7. A method for manufacturing a semiconductor memory device, comprising:
alternately stacking a first film and an insulating film to form a stacked body;
forming a hole in the stacked body;
forming a cover insulating film on an inner surface of the hole;
oxidizing an edge portion of the first film through the cover insulating film;
forming a charge storage film on an exposed surface of the cover insulating film in the hole;
forming a tunnel insulating film on an exposed surface of the charge storage film in the hole;
forming a semiconductor pillar in the hole;
forming a slit in the stacked body;
removing the first film through the slit to form a recess;
removing a portion of the cover insulating film through the recess; and
forming an electrode film in the recess.

8. The method for manufacturing a semiconductor memory device according to claim 7, wherein
the oxidizing of the edge portion of the first film includes performing radical oxidation.

9. The method for manufacturing a semiconductor memory device according to claim 7, wherein
the oxidizing of the edge portion of the first film includes performing plasma oxidation.

10. The method for manufacturing a semiconductor memory device according to claim 7, wherein
the oxidizing of the edge portion of the first film includes performing ISSG oxidation.

11. The method for manufacturing a semiconductor memory device according to claim 7, wherein
the oxidizing of the edge portion of the first film includes performing LPRO.

12. A method for manufacturing a semiconductor memory device, comprising:
alternately stacking a first film and an insulating film to form a stacked body;
forming a hole in the stacked body;
oxidizing an edge portion of the first film through the hole;
forming a cover insulating film on an inner surface of the hole;
forming a charge storage film on the cover insulating film in the hole;
forming a tunnel insulating film on the charge storage film in the hole;
forming a semiconductor pillar in the hole;
forming a slit in the stacked body;
removing the first film through the slit to form a recess;
removing a portion of the cover insulating film through the recess;
forming a barrier metal film on an inner surface in the recess; and
forming an electrode film in the recess.

13. The method for manufacturing a semiconductor memory device according to claim 12, wherein
the oxidizing of the edge portion of the first film on a side of the hole includes performing radical oxidation.

14. The method for manufacturing a semiconductor memory device according to claim 12, wherein
the oxidizing of the edge portion of the first film on a side of the hole includes performing plasma oxidation.

15. The method for manufacturing a semiconductor memory device according to claim 12, wherein
the oxidizing of the edge portion of the first film on a side of the hole includes performing ISSG oxidation.

16. The method for manufacturing a semiconductor memory device according to claim 12, wherein
the oxidizing of the edge portion of the first film on a side of the hole includes performing LPRO.
